(19) United States
(12) Patent Application Publication
(10) Pub. No.: US 2013/0093429 A1
(43) Pub. Date: Apr. 18, 2013

(54) BATTERY GAUGE ESTIMATION DEVICE

(71) Applicant: Richtek Technology Corporation, Zhubei City (TW)

(72) Inventors: Pei-Cheng HUANG, Taipei City (TW); Chiu-Yi CHI, Zhubei City (TW); Cheng-Yuan CHEN, Taipei City (TW)

(73) Assignee: RICHTEK TECHNOLOGY CORPORATION, Zhubei City (TW)

(21) Appl. No.: 13/633,613

(22) Filed: Oct. 2, 2012

(30) Foreign Application Priority Data
Oct. 14, 2011 (TW) 100137447

(51) Int. Cl. G01R 31/36

(52) U.S. Cl. 324/433; 324/426

(57) ABSTRACT

A battery gauge estimation device is disclosed, having an impedance element, a switch, a control circuit, a voltage detection circuit, and an estimation circuit. The impedance element is coupled between a first terminal and a second terminal of a battery, and the switch is coupled between the impedance element and the first terminal of the battery. The control circuit configures the switch to be intermittently conducted at a predetermined frequency. The voltage detection circuit detects the voltage difference between the terminals of the impedance element. The estimation circuit generates a remaining power estimation according to the detected voltage difference.

### CROSS-REFERENCE TO RELATED APPLICATIONS

This application claims the benefit of priority to Taiwanese Patent Application No. 100137447, filed on Oct. 14, 2011; the entirety of which is incorporated herein by reference for all purposes.

### BACKGROUND

The present disclosure generally relates to a battery gauge estimation device and, more particularly, to the battery gauge estimation device with improved accuracy.

Along with the advances in the battery technology, many portable devices powered by the battery have longer operation time and already become necessaries in the human life. For example, the popularity of electric vehicles and hybrid vehicles make the battery indispensable in the transportation. When the battery-powered electronic devices operate, the user must monitor the remaining power of the battery so as to charge or replace the battery in due course.

In some applications, a resistor is connected in series with a battery to estimate the remaining power of the battery by monitoring the voltage or the current of the resistor and the battery. The serially connected resistor, however, constantly consumes power. Moreover, when modern electronic devices are more and more energy conserving, the power consumed by the serially connected resistor cannot be neglected.

On the other hand, many new types of batteries possess very different characteristics. For example, some batteries are designed to provide almost the same amount of voltage and current when the remaining power of the battery locates between 10%˜90%. It is therefore not accurate to calculate the remaining power of this battery with traditional approaches.

### SUMMARY

In view of the foregoing, it can be appreciated that a substantial need exists for methods and apparatuses that can mitigate or reduce the problems above.

An example embodiment of a battery gauge estimation device, comprising: an impedance element for coupling with a first terminal and a second terminal of a battery; a first switch for coupling between the impedance element and the first terminal of the battery; a control circuit for configuring the first switch to be intermittently conducted at a first frequency in a first period and to be intermittently conducted at a second frequency in a second period; a current detection circuit, coupled with the impedance element, for detecting a first current flowing through the impedance element in the first period and for detecting a second current flowing through the impedance element in the second period; and an estimation circuit for generating a remaining power estimation according to at least one of the first current, the second current, a first AC impedance of the impedance element when the first current flows through the impedance element, and a second AC impedance of the impedance element when the second current flows through the impedance element.

An example embodiment of a battery gauge estimation device, comprising: an impedance element for coupling with a first terminal and a second terminal of a battery; a first switch for coupling between the impedance element and the first terminal of the battery; a control circuit for configuring the first switch to be intermittently conducted at a first frequency in a first period; a voltage detection circuit, coupled with the impedance element, for detecting a first voltage difference between terminals of the impedance element in the first period; and an estimation circuit for generating a remaining power estimation according to at least one of the first voltage difference and a first AC impedance of the impedance element when the first voltage difference is applied on the impedance element.

An example embodiment of a battery gauge estimation device, comprising: an impedance element for coupling with a first terminal and a second terminal of a battery; a transistor for coupling between the impedance element and the first terminal of the battery; a control circuit for configuring the first switch to be conducted in a first period and configuring a voltage at a control terminal of the transistor to periodically vary at a first frequency; a voltage detection circuit, coupled with the impedance element, for detecting a first voltage difference between terminals of the impedance element in the first period; and an estimation circuit for generating a remaining power estimation according to at least one of the first voltage difference.

It is to be understood that both the foregoing general description and the following detailed description are example and explanatory only and are not restrictive of the invention, as claimed.

### BRIEF DESCRIPTION OF THE DRAWINGS

FIG. 1 shows a simplified functional block diagram of an example electronic device.

FIG. 2 shows a simplified timing diagram of the control signals generated by the control circuit in FIG. 1.

FIG. 3 shows a partial content of an example lookup table.

FIG. 4 shows a partial content of another example lookup table.

FIG. 5 shows an Id-Vgs characteristic curve of an example transistor.

All of the drawings are arranged in accordance with at least some embodiments described herein.

### DETAILED DESCRIPTION

Reference will now be made in detail to embodiments of the invention, which are illustrated in the accompanying drawings.

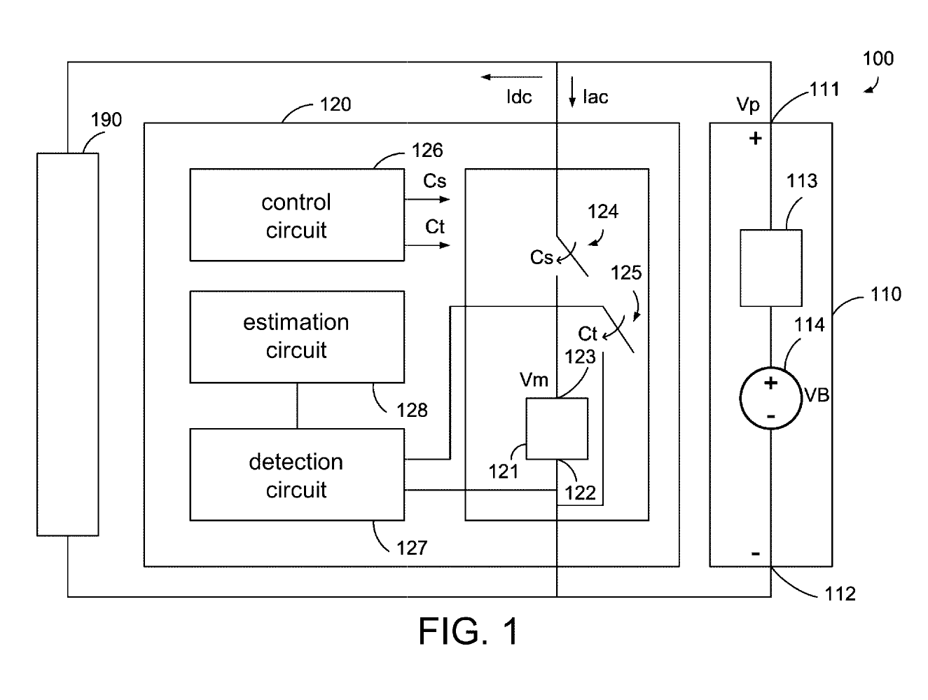

FIG. 1 shows a simplified functional block diagram of an example electronic device 100. The electronic device 100 comprises a battery 110 and a battery gauge estimation device 120. The other components of the electronic device 100 are collectively expressed with a block 190 in FIG. 1. Other components and connections are omitted in FIG. 1 for the purposes of conciseness and easier explanation.

The battery 110 provides the current Idc to the electronic device 100 with an anode terminal 111 and a cathode terminal 112. The battery 110 may be equivalently expressed as an impedance element 113 and a power source 114. The impedance Z113 of the impedance element 113 equals to R113+1/(2π·f·C113), wherein R113 is the resistance of the impedance element 113, C113 is the capacitance of the impedance element 113, and f is the frequency of the current flowing through the impedance element 113. The impedance Z113 of the impedance element 113 and the output voltage and the output current of the power source 114 vary with the remaining power of the battery 110. In FIG. 1, the voltage at the anode 111 is denoted as Vp, and the voltage of the power source is denoted as VB.

The battery gauge estimation device 120 is coupled between with the anode 111 and the cathode 112 of the battery 110, and comprises an impedance element 121, switches 124 and 125, a control circuit 126, a detection circuit 127, and an estimation circuit 128.

One terminal 122 of the impedance element 121 is coupled with the cathode 112 of the battery 110, and the other terminal 123 of the impedance element 121 is coupled with the anode 111 or the cathode 112 according to the conduction statuses of the switches 124 and 125 configured by the control signals Cs and Ct. The impedance of the impedance element 121 is referred to as Z121 herein. In FIG. 1, the voltage at the terminal 123 of the impedance element 121 is denoted as Vm.

The control circuit 126 is used to generate the control signals Cs and Ct for configuring the conduction statuses of the switches 124 and 125.

The detection circuit 127 is used to detect the voltages at the two terminals 122 and 123 of the impedance element 121, the voltage difference between the two terminals 122 and 123 of the impedance element 121, and/or the value of the current flowing through the impedance element 121. The detected voltage(s), the detected voltage difference, and/or the detected current value are transmitted to the estimation circuit 128. For example, the detection circuit may be realized with a voltage detection circuit and/or a current detection circuit.

The estimation circuit 128 may generate an estimation value of the remaining power of the battery 110 by searching in a lookup table according to the detected voltage(s), the detected voltage difference, and/or the detected current transmitted by the detection circuit 127. The lookup table may be stored in the volatile memory and/or in the non-volatile memory in the interior or the exterior of the battery gauge estimation device 120.

The control circuit 126, the detection circuit 127, and the estimation circuit 128 may be respectively realized with processors, controllers, analog circuit elements, digital circuit elements, other suitable hardware, firmware, software, and/or the combination thereof.

In some type of batteries, even if the remaining powers of the battery 110 are different, the DC impedance values R113 of the impedance element 113 may not have too much difference. It is therefore not possible to accurately estimate the remaining power of the battery 110 by measuring the DC impedance values R113. In this embodiment, the control circuit 126 configures the switch 125 to be not conducted and configures the switch 124 to be intermittently conducted so that an AC current lac may flow through the battery gauge estimation device 120. The battery gauge estimation device 120 may therefore estimate the remaining power of the battery 110 more accurately by measuring the AC impedance Z113 of the impedance element 113.

For example, the control circuit 126 configures the switch 125 to be not conducted and configures the switch 124 to be conducted at a frequency f1. The terminal 123 of the impedance element 121 is intermittently coupled with the terminal 111 of the battery 110 so that the AC current lac may flow through the battery gauge estimation device 120. The voltage Vp at the terminal 111 of the battery 110 is Vp=(Idc+lac)*Z113+VB=(Idc+lac)*[R113+1/(2π·f1·C113)]+VB, wherein lac =Vm/Z121.

The estimation circuit 128 may therefore calculate the AC impedance Z113=R113+1/(2π·f1·C113) to estimate the remaining power of the battery 110 according to the above equations and the detected voltage, the detected voltage difference, and/or the detected current transmitted by the detection circuit 127. For example, the estimation circuit 128 may search the lookup table to obtain a remaining power estimation of the battery 110 according to the calculated AC impedance Z113(f1)=R113+1/(2π·f1·C113).

In another embodiment, the control circuit 126 may configures the switch 125 to be not conducted and configures the switch 124 to be conducted at a frequency f2. The terminal 123 of the impedance element 121 is intermittently coupled with the terminal 110 of the battery 110 so that the AC current lac may flow through the battery gauge estimation device 120. The voltage Vp at the terminal 111 of the battery 110 is Vp=(Idc+lac)*Z113+VB=(Idc+lac)*[R113+1/(2π·f2·C113)]+VB, wherein lac =Vm/Z121.

The estimation circuit 128 may calculate the AC impedances Z113=R113+1/(2π·f1·C113) and Z113=R113+1/(2π·f2·C113) to estimate the remaining power of the battery 110 according to the above equations and the detected voltage, the detected voltage difference, and/or the detected current transmitted by the detection circuit 127. For example, the estimation circuit 128 may search the lookup table to obtain a remaining power estimation of the battery 110 according to the calculated AC impedances Z113(f1)=R113+1/(2π·f1·C113) and Z113(f2)=R113+1/(2π·f2·C113).

In other embodiments, the control circuit 126 may configures the switch 125 to be not conducted and configures the switch 124 to be conducted at one or more predetermined frequencies. The estimation circuit 128 may calculate the AC impedance(s) Z113 at different frequencies to estimate the remaining power of the battery 110 according to the lookup table and according to at least one of the detected voltage, the detected voltage difference, and the detected current transmitted by the detection circuit 127. Thus, the estimation circuit 128 may search the lookup table to obtain the remaining power estimation of the battery 110 according to the calculated AC impedance Z113 at one or more frequencies.

In other embodiments, the estimation circuit 128 may also directly calculate the remaining power estimation with one or more predetermined equations according to the AC impedance of the impedance element 113, the detected voltage, the detected voltage difference, and/or the detected current transmitted by the detection circuit 127.

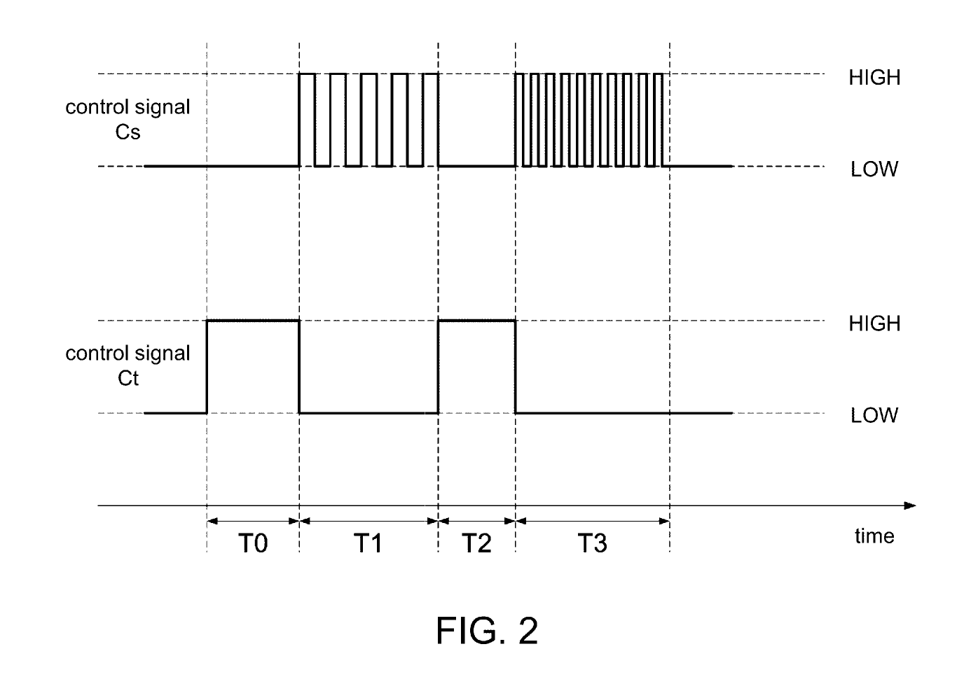

FIG. 2 shows a simplified timing diagram of the control signals Cs and Ct generated by the control circuit 126 in FIG. 1 when the battery gauge estimation device 120 performs the remaining power estimations on the battery 110.

In the period of time T0 in FIG. 2, the control circuit 126 configures the control signal Cs to be low and configures the controls signal Ct to be high so that the switch 124 is not conducted and the switch 125 is conducted. The terminal 123 of the impedance element 121 is coupled with the cathode 112 of the battery 110 and the voltage difference between the terminals 122 and 123 of the impedance element 121 is 0. The AC current lac(T0) flowing from the battery 110 into the battery gauge estimation device 120 is 0.

In the period of time T1 in FIG. 2, the control circuit 126 configures the control signal Ct to be low and configures the controls signal Cs to be high at a frequency f1 so that the switch 125 is not conducted and the switch 124 is conducted between the terminal 123 of the impedance element 121 and the anode 111 of the battery 110 at the frequency f1. The AC current lac(T1) flows from the battery 110 through the switch 124 and the impedance element 121 of the battery gauge estimation device 120.

The detection circuit 127 detects the value of the AC current lac(T1) flowing through the impedance element 121, the voltage(s) at the terminal(s) of the impedance element 121 and/or the voltage difference between the terminals of the impedance element 121, and transmits the detected current lac(T1), the detected voltage(s), and/or the detected voltage difference to the estimation circuit 128.

In the period T2 in FIG. 2, the control circuit 126 configures the control signal Cs to be low and configures the controls signal Ct to be high so that the switch 124 is not conducted and the switch 125 is conducted. The terminal 123 of the impedance element 121 is coupled with the cathode 112 of the battery 110 and the voltage difference between the terminals 122 and 123 of the impedance element 121 is 0. The AC current lac(T2) flowing from the battery 110 into the battery gauge estimation device 120 is 0.

In the period of time T3 in FIG. 2, the control circuit 126 configures the control signal Ct to be low and configures the controls signal Cs to be high at a frequency f2 so that the switch 125 is not conducted and the switch 124 is conducted between the terminal 123 of the impedance element 121 and the anode 111 of the battery 110 at the frequency f2. The AC current lac(T3) flows from the battery 110 through the switch 124 and the impedance element 121 of the battery gauge estimation device 120.

The detection circuit 127 detects the value of the AC current lac(T3) flowing through the impedance element 121, the voltage(s) at the terminal(s) of the impedance element 121 and/or the voltage difference between the terminals of the impedance element 121, and transmits the detected current lac(T3), the detected voltage(s), and/or the detected voltage difference to the estimation circuit 128.

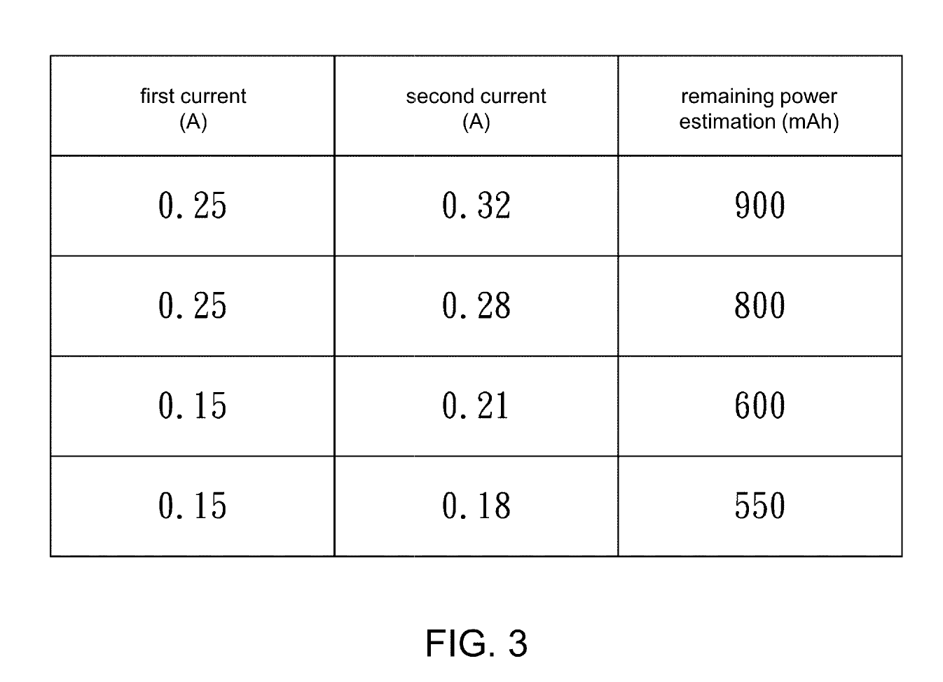

In one embodiment, the estimation circuit 128 searches the lookup table according to the detected currents lac(T1) and lac(T3) to generated the remaining power estimation of the battery 110. FIG. 3 shows a partial content of an example lookup table. In the lookup table in FIG. 3, the estimation circuit 128 searches the lookup table according to the detected currents lac(T1) and Iac(T3) to generated the remaining power estimation of the battery 110. For example, when the first current lac(T1) is 0.25 ampere (A) and the second current Iac(T3) is 0.28 A, the estimation circuit 128 searches the table in FIG. 3 and accordingly generates a remaining power estimation of 800 ampere-hour (mAh) for the battery 110.

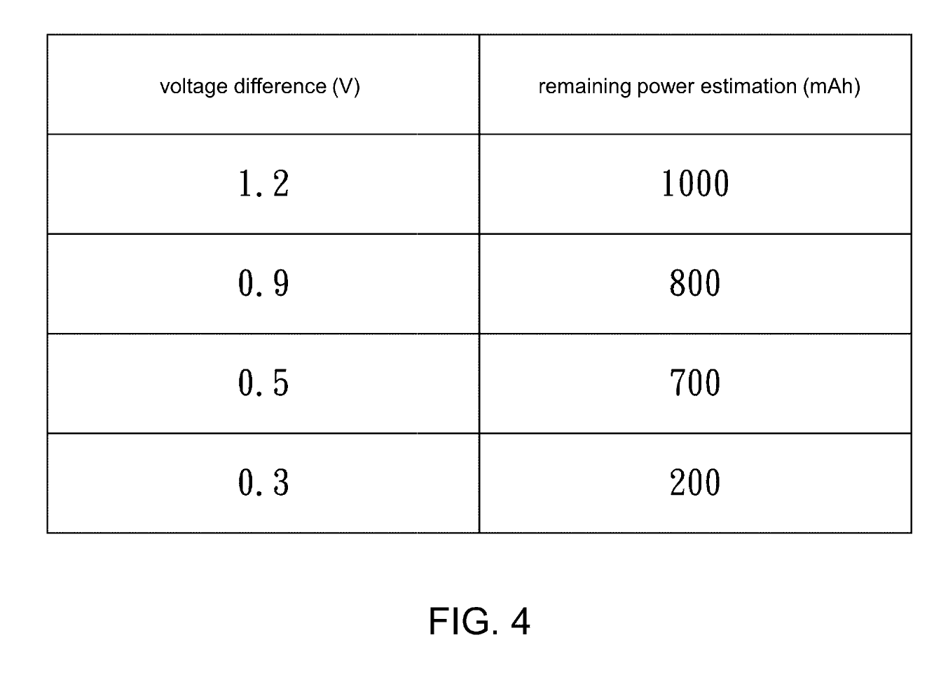

In another embodiment, the estimation circuit 128 searches another lookup table according to the detected voltage(s) and/or the detected voltage difference of the impedance element 121 in the period of time T1 and/or T3 to generate the remaining power estimation of the battery 110. FIG. 4 shows a partial content of another example lookup table. For example, when the voltage difference is 0.9 volt (V), the estimation circuit 128 searches the table in FIG. 4 and accordingly generates a remaining power estimation of 800 mAh for the battery 110.

In other embodiments, the estimation circuit 128 may generate a remaining power estimation of the battery 110 according to the lookup table and according to at least one of the AC impedance of the impedance element 113, the detected voltage(s), the detected voltage difference, and the detected current.

In the embodiments herein, the switches 124 and/or 125 may be realized with the transistor, e.g., the MOSFET, the BJT, or other suitable types of transistors.

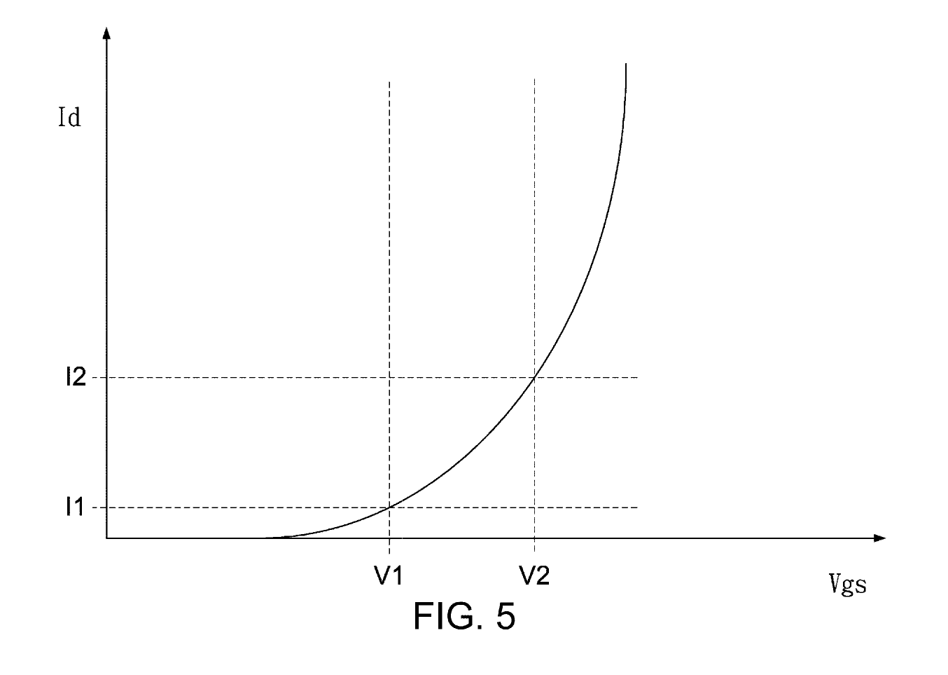

For example, in one embodiment, the switch 124 is realized with a MOSFET, which possess an Id-Vgs characteristic curve as shown in FIG. 5. The control circuit 126 may configures the voltage at the gate (i.e., the control terminal of the MOSFET) of the MOSFET by the control signal Cs for configuring the drain current Id (i.e., the current flowing through the switch 124).

Therefore, in the periods of time T1 and T3, the control circuit 126 may configures the switch 125 to be not conducted by the control signal Ct and configures the voltage at the control terminal of the switch 124 by the control signal Cs. Therefore, in FIG. 5, the voltage at the control terminal of the switch 124 varies between the voltages V1 and V2 at the frequencies f1 and f2 and accordingly the currents lac(T1) and lac(T3) flowing through the switch 124 varies between the currents 11 and 12 at the frequencies f1 and f2, respectively in the periods of time T1 and T3.

In the embodiments above, the control signal Cs may be realized with square waves, sinusoidal waves, sawtooth waves, or other periodic signals in the periods of time T1 and T3.

In the embodiments above, the detection circuit 127 may calculate the average, the weight average, the maximum, the minimum, and/or other suitable arithmetic values of the detected voltage(s), the detected voltage difference, and/or the detected current of the impedance element 121. The calculated value are transmitted to the estimation circuit 128 so that the estimation circuit 128 may search the lookup table according to the calculated value to generate the remaining power estimation of the battery 110.

In the embodiments above, the lookup table may records the remaining power estimation values respectively corresponding to one or more AC impedances of the impedance element 113, one or more detected voltages at the terminals of the impedance element 121, one or more detected voltage differences at the terminals of the impedance element 121, and/or one or more detected currents at the terminals of the impedance element 121.

The lookup table may records the relation of a remaining power estimation value corresponding to a specific value, and may also records the relation of a remaining power estimation value corresponding to a specific range. For example, the lookup table in FIG. 4 may also be configured so that the remaining power estimation is 200 mAh when the detected voltage difference of the impedance element 121 locates between 0.3 volt and 0.33 volt.

In the embodiments above, the detection circuit 127 may be configured to detect the voltage difference between the anode 111 and the cathode 112 of the battery 110. For example, in the embodiment in FIG. 3, the detection circuit 127 detects the voltage difference between the anode 111 and the cathode 112 respectively in the periods T1 and T3. The estimation circuit 128 may search the lookup table according to the detected voltage difference in the periods T1 and T3 to generate the remaining power estimation of the battery 110.

In the embodiments above, the AC current lac flows from the battery 110 to the battery gauge estimation device 120. In other embodiments, the AC current lac may also be configured to flow form the battery gauge estimation device 120 to the battery 110 for performing the remaining power estimation.

In the embodiments above, the lookup table may record suitable types of the remaining power estimation, e.g., the percent of battery capacity.

In the embodiments above, the lookup table may be generated by testing a plurality of batteries. Besides, in some applications, the content of the lookup table may also be dynamically modified according to the operation of the electronic device 100 or other predetermined updating algorithms.

The battery gauge estimation 120 may perform the remaining power estimation within a short period of time and therefore the power consumption on the remaining power estimation may be reduced. Moreover, the switches 124 and 125 may be configured so that no current flows into the battery gauge estimation device 120 when the battery gauge estimation device 120 does not perform the remaining power estimation of the battery 110. The power consumption of the battery gauge estimation device 120 may therefore be further reduced.

Because the AC impedance varies with the frequency of the AC current, the battery gauge estimation 120 may perform the remaining power estimation more accurately according to the AC impedance of the battery to generate the remaining power estimation even if the DC impedance of the battery does not vary obviously in some voltage range.

In the embodiments above, the signals, e.g., the control signals Cs and Ct, are expressed as active high signals for the purposes of conciseness and easier explanation. In the other embodiments, the signals may be respectively realized with active high signals or active low signals. Some signals, components, circuits, and operations are only described in the voltage form or current form for the purposes of conciseness and easier explanation. In the other embodiments, signals, components, circuits, and operations may be respectively realized in the voltage form or current form.

The same reference numbers may be used throughout the drawings to refer to the same or like parts or components/operations. Certain terms are used throughout the description and following claims to refer to particular components. As one skilled in the art will appreciate, a component may be referred by different names. This document does not intend to distinguish between components that differ in name but not in function. In the following description and in the claims, the term “comprise” is used in an open-ended fashion, and thus should be interpreted to mean “include, but not limited to . . . ” Also, the phrase “coupled with” is intended to compass any indirect or direct connection. Accordingly, if this document mentioned that a first device is coupled with a second device, it means that the first device may be directly or indirectly connected to the second device through electrical connections, wireless communications, optical communications, or other signal connections with/without other intermediate devices or connection means.

As used herein, the term “and/or” includes any and all combinations of one or more of the associated listed items. In addition, the singular forms “a”, “an”, and “the” as used herein are intended to include the plural forms as well, unless the context clearly indicates otherwise.

Other embodiments of the invention will be apparent to those skilled in the art from consideration of the specification and practice of the invention disclosed herein. It is intended that the specification and examples be considered as exemplary only, with a true scope and spirit of the invention being indicated by the following claims.

What is claimed is:

1. A battery gauge estimation device, comprising:
an impedance element for coupling with a first terminal and a second terminal of a battery;
a first switch for coupling between the impedance element and the first terminal of the battery;
a control circuit for configuring the first switch to be intermittently conducted at a first frequency in a first period and to be intermittently conducted at a second frequency in a second period;
a current detection circuit, coupled with the impedance element, for detecting a first current flowing through the impedance element in the first period and for detecting a second current flowing through the impedance element in the second period; and
an estimation circuit for generating a remaining power estimation according to at least one of the first current, the second current, a first AC impedance of the impedance element when the first current flows through the impedance element, and a second AC impedance of the impedance element when the second current flows through the impedance element.

2. The device of claim 1, wherein the estimation circuit generates the remaining power estimation by searching a lookup table according to at least one of the first current, the second current, the first AC impedance, and the second AC impedance.

3. The device of claim 1, further comprising:
a second switch, coupled between the impedance element and the second terminal of the battery;
wherein the control circuit configures the first switch to be not conducted and configures the second switch to be conducted in an interval between the first period and the second period.

4. The device of claim 1, wherein the current detection circuit detects the first current and the second current according to at least one of voltages of terminals of the impedance element, a voltage difference between the terminals of the impedance element, voltages of the first terminal and the second terminal of the battery, and a voltage difference between the first terminal and the second terminal of the battery.

5. The device of claim 2, further comprising:
a second switch, coupled between the impedance element and the second terminal of the battery;
wherein the control circuit configures the first switch to be not conducted and configures the second switch to be conducted in an interval between the first period and the second period.

6. The device of claim 5, wherein the current detection circuit detects the first current and the second current according to at least one of voltages of terminals of the impedance element, a voltage difference between the terminals of the impedance element, voltages of the first terminal and the second terminal of the battery, and a voltage difference between the first terminal and the second terminal of the battery.

7. The device of claim 2, wherein the current detection circuit detects the first current and the second current according to at least one of voltages of terminals of the impedance element, a voltage difference between the terminals of the impedance element, voltages of the first terminal and the second terminal of the battery, and a voltage difference between the first terminal and the second terminal of the battery.

8. The device of claim 3, wherein the current detection circuit detects the first current and the second current according to at least one of voltages of terminals of the impedance element, a voltage difference between the terminals of the impedance element, voltages of the first terminal and the second terminal of the battery, and a voltage difference between the first terminal and the second terminal of the battery.

9. A battery gauge estimation device, comprising:
an impedance element for coupling with a first terminal and a second terminal of a battery;
a first switch for coupling between the impedance element and the first terminal of the battery;
a control circuit for configuring the first switch to be intermittently conducted at a first frequency in a first period;
a voltage detection circuit, coupled with the impedance element, for detecting a first voltage difference between terminals of the impedance element in the first period; and
an estimation circuit for generating a remaining power estimation according to at least one of the first voltage difference and a first AC impedance of the impedance element when the first voltage difference is applied on the impedance element.

10. The device of claim 9, wherein the voltage detection circuit may detect the first voltage difference by detecting a second voltage difference between the first terminal and the second terminal of the battery; and the estimation circuit generates the remaining power estimation according to at least one of the first voltage difference, the first AC impedance, the second voltage difference, and a second AC impedance of the impedance element when the second voltage difference is applied on the impedance element.

11. The device of claim 10, wherein the control circuit configures the first switch to be intermittently conducted at a second frequency in a second period; the voltage detection circuit detects a third voltage difference between the terminals of the impedance element; and the estimation circuit generates the remaining power estimation according to at least one of the first voltage difference, the second voltage difference, and the third voltage difference.

12. The device of claim 11, wherein the voltage detection circuit detects the third voltage difference by detecting a fourth voltage difference between the first terminal and the second terminal of the battery; and the estimation circuit generates the remaining power estimation according to at least one of the first voltage difference, the second voltage difference, the third voltage difference, and the fourth voltage difference.

13. The device of claim 9, further comprising:
a second switch, coupled between the impedance element and the second terminal of the battery;
wherein the control circuit configures the first switch to be not conducted and configures the second switch to be conducted in an interval between the first period and the second period.

14. A battery gauge estimation device, comprising:
an impedance element for coupling with a first terminal and a second terminal of a battery;
a transistor for coupling between the impedance element and the first terminal of the battery;
a control circuit for configuring the first switch to be conducted in a first period and configuring a voltage at a control terminal of the transistor to periodically vary at a first frequency;
a voltage detection circuit, coupled with the impedance element, for detecting a first voltage difference between terminals of the impedance element in the first period; and
an estimation circuit for generating a remaining power estimation according to at least one of the first voltage difference.

15. The device of claim 14, wherein the voltage detection circuit may detect the first voltage difference by detecting a second voltage difference between the first terminal and the second terminal of the battery; and the estimation circuit generates the remaining power estimation according to at least one of the first voltage difference and the second voltage difference.

16. The device of claim 15, wherein the control circuit configures the voltage at the control terminal of the transistor to periodically vary at a second frequency in a second period; the voltage detection circuit detects a third voltage difference between the terminals of the impedance element; and the estimation circuit generates the remaining power estimation according to at least one of the first voltage difference, the second voltage difference, and the third voltage difference.

17. The device of claim 16, wherein the voltage detection circuit detects the third voltage difference by detecting a fourth voltage difference between the first terminal and the second terminal of the battery; and the estimation circuit generates the remaining power estimation according to at least one of the first voltage difference, the second voltage difference, the third voltage difference, and the fourth voltage difference.

18. The device of claim 14, further comprising:
a second switch, coupled between the impedance element and the second terminal of the battery;
wherein the control circuit configures the first switch to be not conducted and configures the second switch to be conducted in an interval between the first period and the second period.

19. The device of claim 15, wherein the voltage detection circuit generates one or more detected currents according to at least one of the first voltage difference and the second voltage difference; and the estimation circuit generate the remaining power estimation according to at least one of the detected current(s).

20. The device of claim 15, wherein the voltage detection circuit generates one or more AC impedances according to at least one of the first voltage difference and the second voltage difference; and the estimation circuit generate the remaining power estimation according to at least one of the AC impedance(s).
